(19) United States
(12) Patent Application Publication
(10) Pub. No.: US 2013/0239894 A1
(43) Pub. Date: Sep. 19, 2013

(54) CHEMICAL VAPOR DEPOSITION APPARATUS

(71) Applicants: Cheng Chia FANG, Taipei City (TW); Heng LIU, Sunnyvale, CA (US)

(72) Inventors: Cheng Chia FANG, Taipei City (TW); Heng LIU, Sunnyvale, CA (US)

(73) Assignee: PINECONE MATERIAL INC., Taipei City (TW)

(21) Appl. No.: 13/424,157

(22) Filed: Mar. 19, 2012

(51) Int. Cl. C23C 16/458; C23C 16/46

(52) U.S. Cl. 118/725; 118/730; 118/724

(57) ABSTRACT

A chemical vapor deposition (CVD) apparatus includes at least one susceptor mounted in a non-horizontal position, and at least one holder rotatably mounted on a first surface of the susceptor for holding wafers. The holder may be rotatable around a holder axis. A showerhead may be mounted at or near a center of the susceptor. The showerhead may release a reaction gas that flows radially toward a periphery of the susceptor. The holder may have a mass center that is eccentric from the holder axis to allow movement relative to the susceptor when the susceptor rotates.

### BACKGROUND OF THE INVENTION

1. Field of the Invention

The present invention generally relates to chemical vapor deposition (CVD), and more particularly to a CVD apparatus having a susceptor that is mounted in a non-horizontal manner.

2. Description of Related Art

Chemical vapor deposition (CVD) is a semiconductor process used to produce thin films. A conventional CVD apparatus typically includes a graphite susceptor that is horizontally placed in a chamber. A showerhead located above the susceptor is used to provide a reaction gas to one or more wafers supported on the susceptor. The reaction gas then reacts on the wafers to produce desired films on the wafers.

As the susceptor is generally designed to capably hold a large number of wafers, a large area may be required to accommodate the CVD apparatus. Because of the large area occupied by the CVD apparatus, the number of CVD apparatus that can be located in a semiconductor manufacturing factory may be limited. Because conventional CVD apparatus are bulky and area consuming, there is a need for novel CVD apparatus or systems that take less area in the semiconductor manufacturing factory.

### SUMMARY

In certain embodiments, a chemical vapor deposition (CVD) apparatus occupies less area than conventional CVD apparatus, such that more CVD apparatuses can be located in a semiconductor manufacturing factory. In some embodiments, a CVD system stacks a number of CVD apparatuses to further enhance efficiency in area, mass production, or cost.

In certain embodiments, a chemical vapor deposition (CVD) apparatus includes at least one susceptor and at least one holder. The susceptor is mounted in a non-horizontal position. The holder is rotatably mounted on a first surface of the susceptor for holding one or more wafers, the holder being rotatable around a holder axis. In some embodiments, the CVD apparatus includes a showerhead mounted at or near a center of the susceptor. A reaction gas may be released from the showerhead and flow radially toward a periphery of the susceptor. In some embodiments, the holder has a mass center that is eccentric from the holder axis. The eccentric mass center allows the holder to have movement relative to the susceptor when the susceptor rotates.

### BRIEF DESCRIPTION OF THE DRAWINGS

FIG. 1A shows a cross-sectional side view of an embodiment of a chemical vapor deposition (CVD) apparatus.

FIG. 1B shows a cross-sectional side view of another embodiment of the CVD apparatus.

FIG. 2 shows an elevational view of the susceptor taken from a pair of broken lines 2-2 of FIGS. 1A and 1B;

FIGS. 3A-3D show representations of embodiments of a holder.

FIG. 4 shows a cross-sectional side view of an additional embodiment of a CVD apparatus.

FIG. 5 shows a cross-sectional side view of another additional embodiment of a CVD apparatus.

FIG. 6 shows a cross-sectional side view of yet another embodiment of a CVD apparatus.

FIG. 7 shows an elevational view of the susceptor taken from a pair of broken lines 7-7 of FIG. 6.

FIG. 8 shows a cross-sectional side view of an embodiment of a vertically stacked CVD system.

FIG. 9 shows a top view of an embodiment of a horizontally stacked CVD system.

FIG. 10 shows a top view of an embodiment of a horizontally stacked CVD system without a chamber wall.

FIG. 11 shows a top view of an embodiment of another horizontally stacked CVD system without the chamber wall.

### DETAILED DESCRIPTION OF EMBODIMENTS

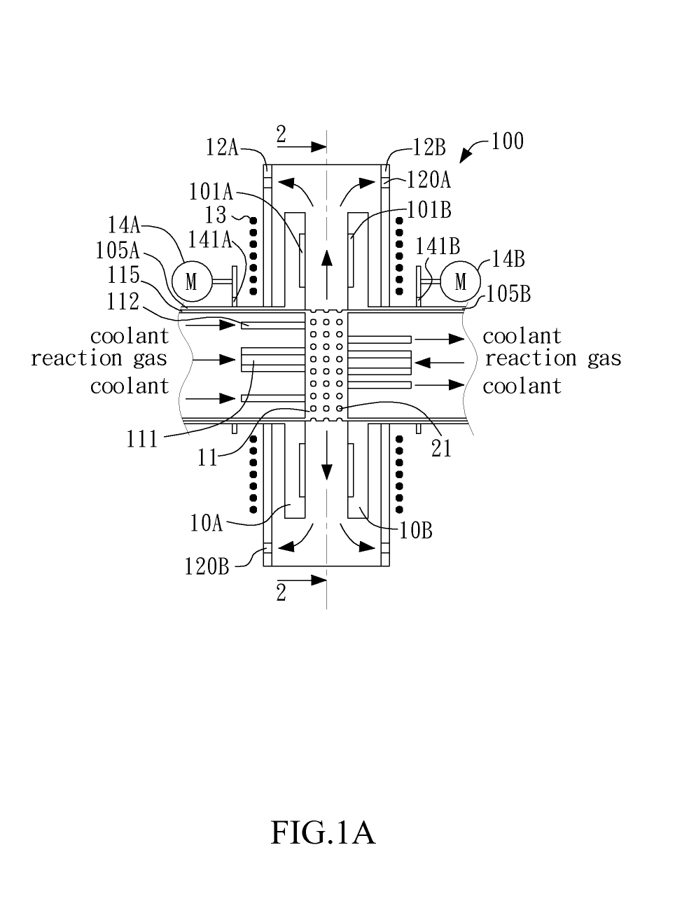

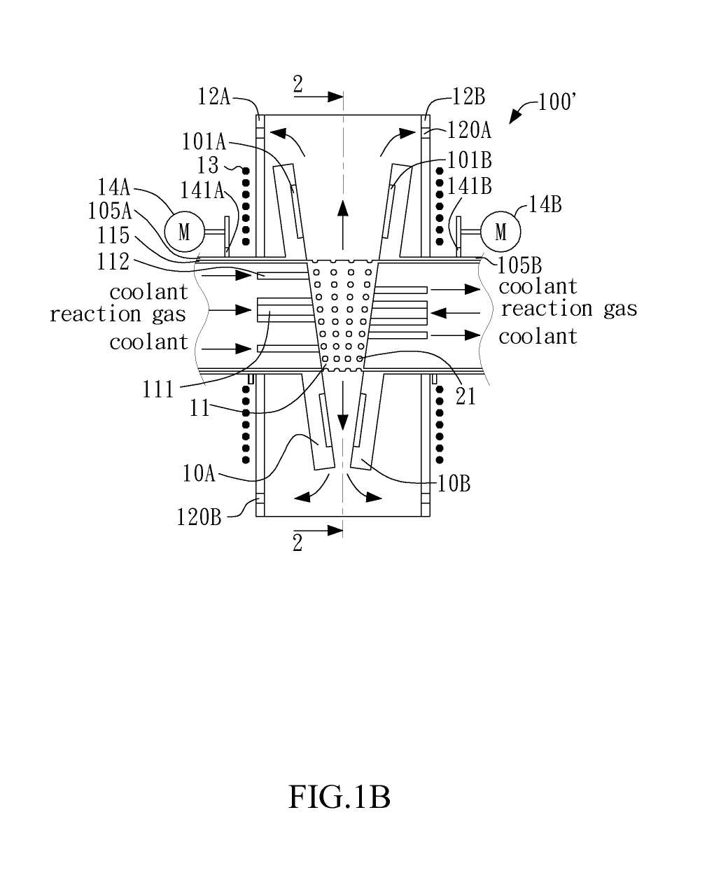

FIG. 1A shows a cross-sectional side view of an embodiment of a chemical vapor deposition (CVD) apparatus. In certain embodiments, CVD apparatus 100 includes at least one susceptor 10 that is mounted in a non-horizontal position. For example, susceptor 10 may be mounted in a substantially vertical position (e.g., a susceptor axis of the susceptor is substantially perpendicular to the direction of gravity). In certain embodiments, CVD apparatus 100, as shown in FIG. 1A, includes two susceptors 10A, 10B that face each other.

FIG. 1B shows a cross-sectional side view of another embodiment of CVD apparatus 100′. In certain embodiments, susceptors 10A, 10B are mounted within an angle of 45° with respect to the direction of gravity. For example, susceptors 10A, 10B may be mounted at an angle of 15° with respect to the direction of gravity, as shown in FIG. 1B.

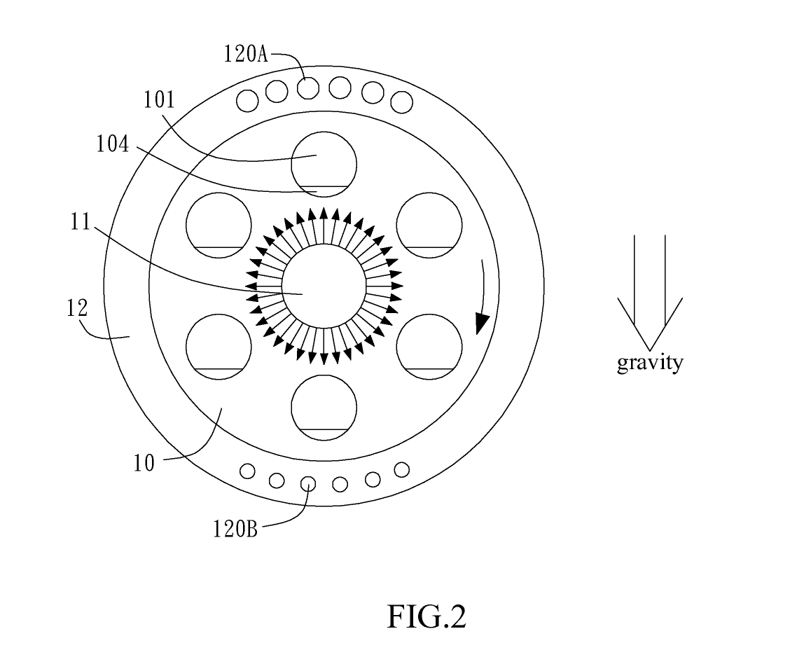

FIG. 2 shows an elevational view of susceptor 10 taken from a pair of broken lines 2-2 of FIGS. 1A and 1B. At least one holder 101 is rotatably mounted on a first (e.g., front) surface of susceptor 10 for holding one or more wafers (not shown). Holder 101 may be, for example, a graphite disc. In certain embodiments, holder 101 is adapted to be rotatable relative to susceptor 10. Holder 101 may be rotatable around a holder axis that is substantially parallel with and distinct from the susceptor axis. It is appreciated by those skilled in the pertinent art that the susceptor axis (or the holder axis) may be a physical axis used to support and rotate susceptor 10 (or holder 101), or the susceptor axis (or the holder axis) may be a virtual (or hypothetical) axis, around which the susceptor (or the holder) rotates.

In some embodiments, one or more securing mechanisms (not shown) may be required to keep holder 101 from falling/dropping from susceptor 10 (e.g., in the embodiment of CVD apparatus 100 shown in FIG. 1A). Securing mechanisms may be omitted in certain embodiments (e.g., the embodiment of CVD apparatus 100′ shown in FIG. 1B).

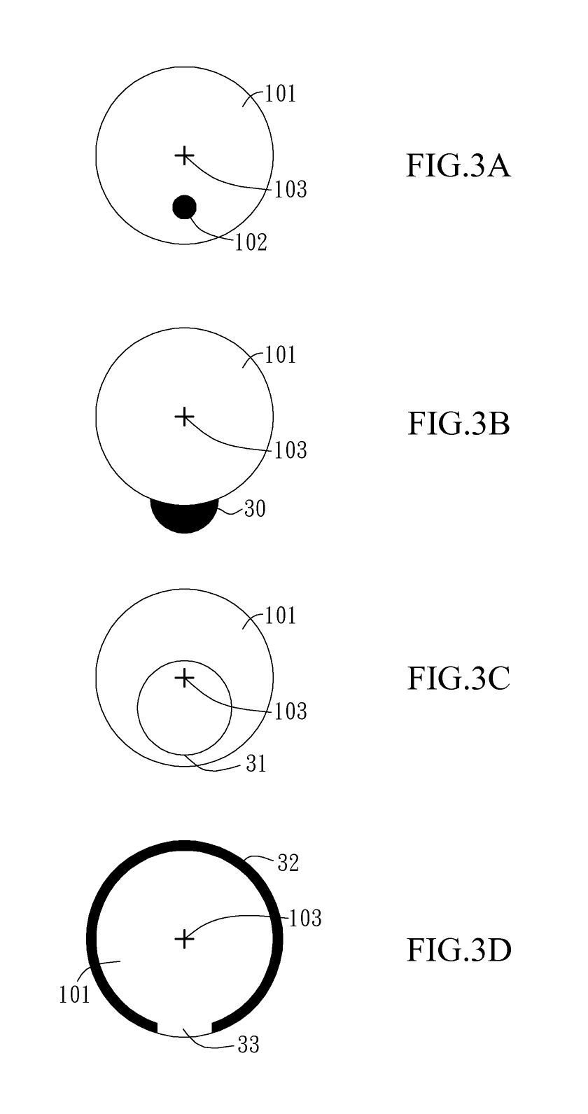

In certain embodiments, as shown in FIG. 3A, holder 101 has a mass center 102 that is eccentric from an area center 103 (or the holder axis). The eccentric mass center allows holder 101 to have movement relative to susceptor 10. In some embodiments, holder 101 includes counterweight 104 (shown in FIG. 2), which makes mass center 102 of holder 101 eccentric from area center 103. Accordingly, as susceptor 10 rotates, holder 101 is kept upright by gravity in a manner similar to a chair on a Ferris wheel. The eccentric mass center 102 may be realized by a variety of implementations. For example, as shown in FIG. 3B, mass 30 may be coupled (e.g., additively attached) at an edge of holder 101. As shown in FIG. 3C, wafers may be placed off-center of the area center 103. The wafers may be located within predetermined range 31 that is eccentric from area center 103. As shown in FIG. 3D, bearing 32 may be placed around holder 101 to allow constrained relative rotation between the holder and susceptor 10. Mass 33 may be further attached at bearing 32 to result in an eccentric mass center. In one exemplary embodiment, the bearing 32 may include an inner bearing and an outer bearing, wherein the former is fixed to the holder 101 and is attached with a mass or counterweight, and the latter is fixed to the susceptor 10. In another exemplary embodiment, the bearing 32 may include a top bearing and a bottom bearing, wherein the former is fixed to the holder 101 and is attached with a mass or counterweight, and the latter is fixed to the susceptor 10.

Referring back to FIGS. 1A, 1B, and 2, showerhead 11 may be mounted at or near a center of susceptor 10. In certain embodiments, as shown in FIGS. 1A and 1B, showerhead 11 is located between two susceptors 10A, 10B such that the showerhead is shared between the two susceptors. Sharing showerhead 11 may substantially reduce the overall cost. In general, showerhead 11 may be shared among more than two susceptors that face each other and are arranged, for example, in a triangular, a rectangular, or a polygonal arrangement.

In certain embodiments, a reaction gas is released from nozzles 21 (denoted by hollow circles) of showerhead 11, and the reaction gas flows radially toward a periphery of susceptors 10A, 10B (as shown by the arrows in FIG. 2) to provide the reaction gas to one or more wafers held on holders 101A, 101B. In certain embodiments, showerhead 11 has a form of a cylinder and the nozzles are formed on the cylindrical surface of the showerhead. At least one gas pipe line 111 and at least one coolant pipe line 112 may be located in showerhead 11 to provide the reaction gas (and/or purge gas) and coolant, respectively.

In certain embodiments, exhaust outlet plates 12A, 12B are located near a second (back) surface of each susceptor 10A, 10B and are fixed with respect to the ground. A plurality of exhaust holes 120A, 120B may be formed on exhaust outlet plates 12A, 12B. In some embodiments, as shown in FIG. 2, (upper) exhaust holes 120A on the upper periphery of exhaust outlet plate 12 have a diameter larger than that of (lower) exhaust holes 120B on the lower periphery of the exhaust outlet plate. As upper exhaust holes 120A may have a flow resistance lower than that of lower exhaust holes 120B, and due to the fact that the reaction gas tends to be pulled downward by gravity, the upper exhaust holes may have a larger drawing force (with respect to the lower exhaust holes) to smoothly and effectively bring out exhaust gas. In certain embodiments, heater 13 is mounted away from the second (back) surfaces of susceptors 10A, 10B for heating the wafers held on holders 101A, 101B.

In certain embodiments, as shown in FIGS. 1A and 1B, susceptors 10A, 10B have rotating shells 105A, 105B that extend away from the second (back) surfaces of the susceptors. Motors 14A, 14B may be used to drive rotating shells 105A, 105B via gears 141A, 141B, thereby rotating susceptors 10A, 10B.

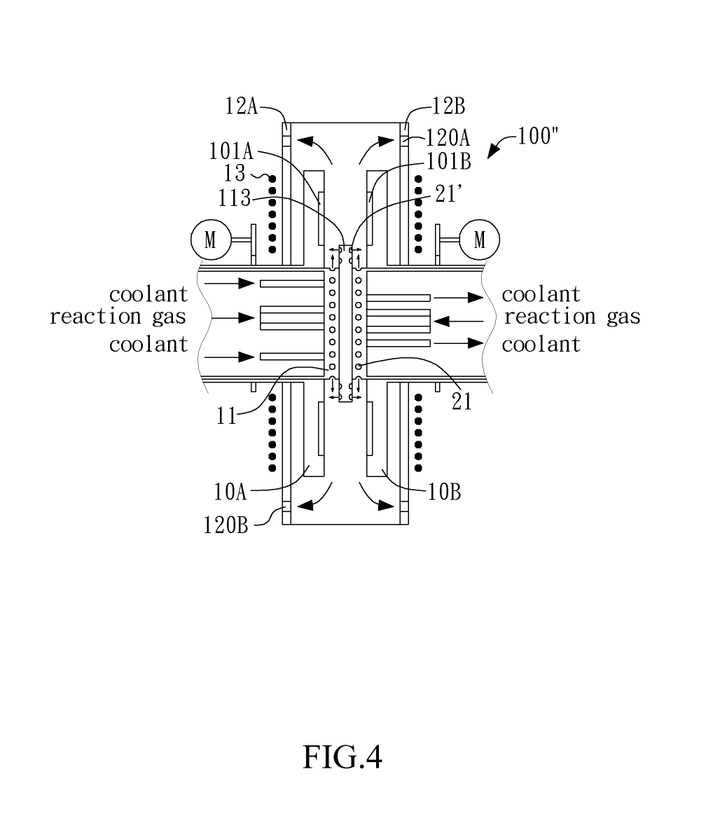

FIG. 4 shows a cross-sectional side view of an additional embodiment of a CVD apparatus. The embodiment of CVD apparatus 100″ shown in FIG. 4 is similar to the embodiment of CVD apparatus 100′, shown in FIG. 1A, with the exception that CVD apparatus 100″ includes flange 113 extending from showerhead 11. Flange 113 may include nozzles 21′ formed on a surface of the flange. The reaction gas released from nozzles 21′ of flange 113 may flow toward the wafers in a direction perpendicular to the radially moving reaction gas released from nozzles 21 of showerhead 11.

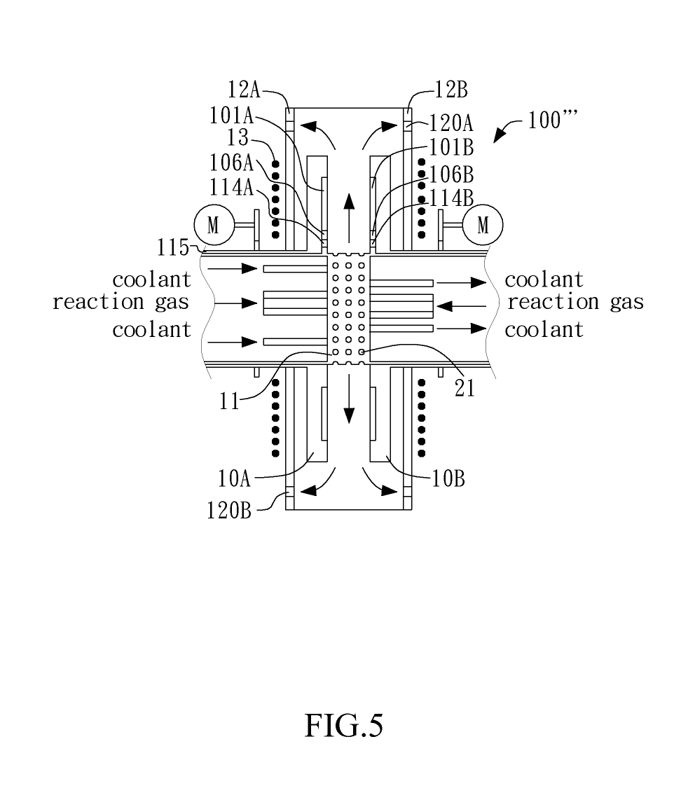

FIG. 5 shows a cross-sectional side view of another additional embodiment of a CVD apparatus. The embodiment of CVD apparatus 100″′ is similar to the embodiment of CVD apparatus 100′, shown in FIG. 1A, with the exception that no counterweight 104 (shown in FIG. 2) is needed in CVD apparatus 100″′. As shown in FIG. 5, instead of the counterweight, holder gears 106A, 106B are attached to periphery of holders 101A, 101B. In certain embodiments, fixed gears 114A, 114B are attached to fixed shell 115 that extends from showerhead 11. As susceptors 10A, 10B rotate, holders 101A, 101B may rotate relative to the susceptors due to the mesh or engagement between holder gears 106A, 106B and fixed gears 114A, 114B.

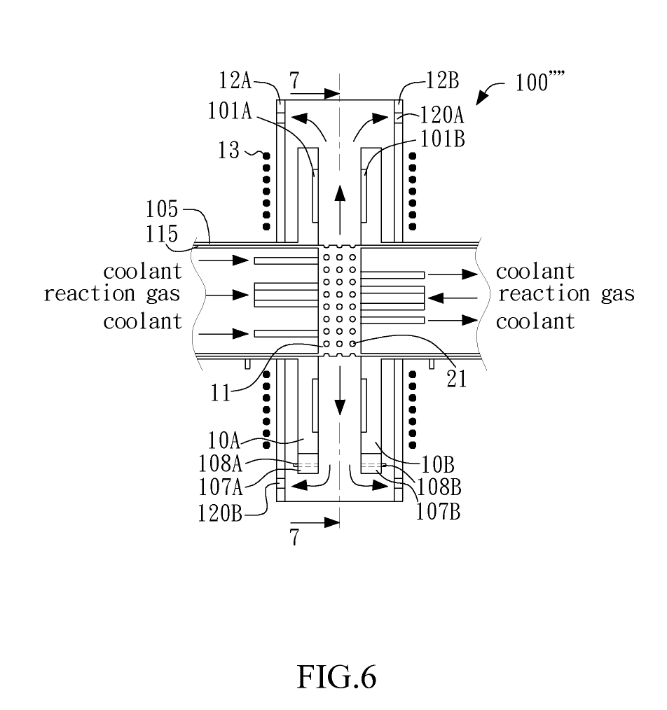

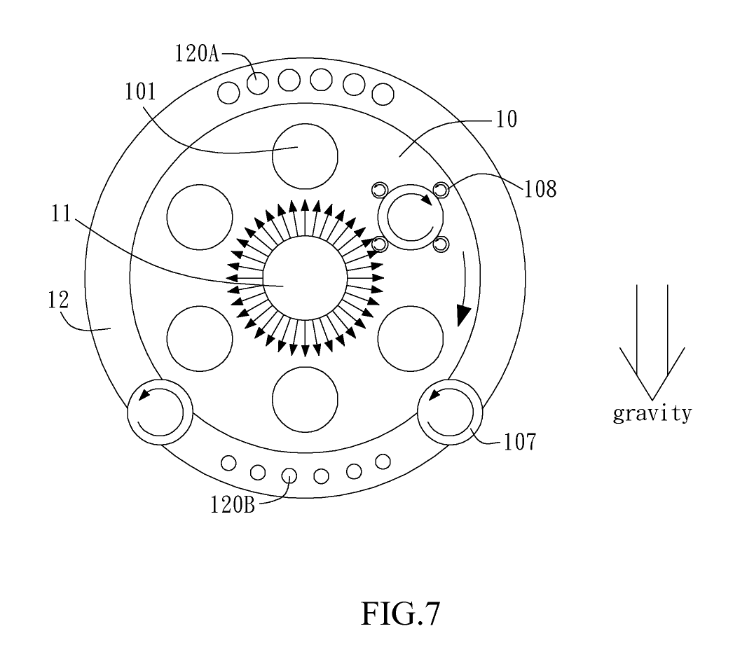

FIG. 6 shows a cross-sectional side view of yet another embodiment of a CVD apparatus, and FIG. 7 shows an elevational view of susceptor 10 taken from a pair of broken lines 7-7 of FIG. 6. The embodiment of CVD apparatus 100″′ is similar to the embodiment of CVD apparatus 100″′, shown in FIG. 5, with the exception that holder gears 106A, 106B and fixed gears 114A, 114B are replaced with one or more susceptor rollers 107A, 107B and one or more holder rollers 108A, 108B. In certain embodiments, susceptor rollers 107A, 107B support and rotate the susceptors 10A, 10B and holder rollers 108A, 108B support and rotate holders 101A, 101B. As described herein, the rotation of holders 101A, 101B may, alternatively, be realized by a physical axis such as a pin (not shown) that supports and drives the holders.

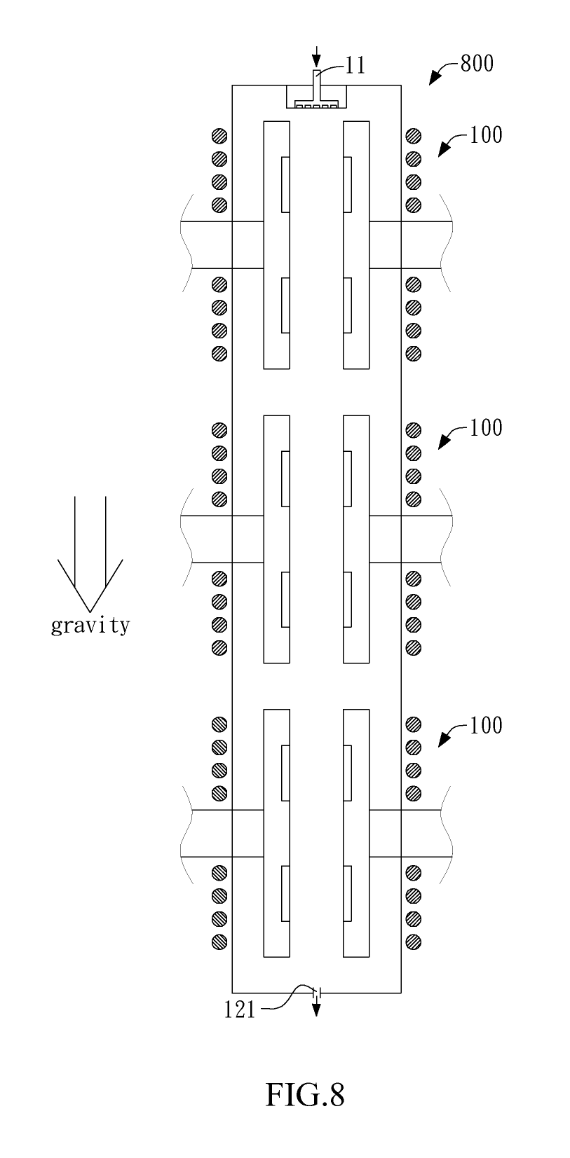

Although a single CVD apparatus has been demonstrated in the preceding embodiments, a number of CVD apparatuses described above may be stacked to build a CVD system. For example, a plurality of CVD apparatuses may be located substantially adjacent to each other in a CVD system (either horizontally or vertically). FIG. 8 shows a cross-sectional side view of an embodiment of a vertically stacked CVD system. CVD system 800 may be made up of a number of CVD apparatuses 100 that are substantially vertically stacked. In certain embodiments, showerhead 11 is mounted at the top of CVD system 800 to provide the reaction gas. Exhaust outlet 121 may be located at the bottom of CVD system 800 for bringing an exhaust gas out of the CVD system. It is noted that showerhead 11 is shared among all the CVD apparatuses, which may reduce overall cost.

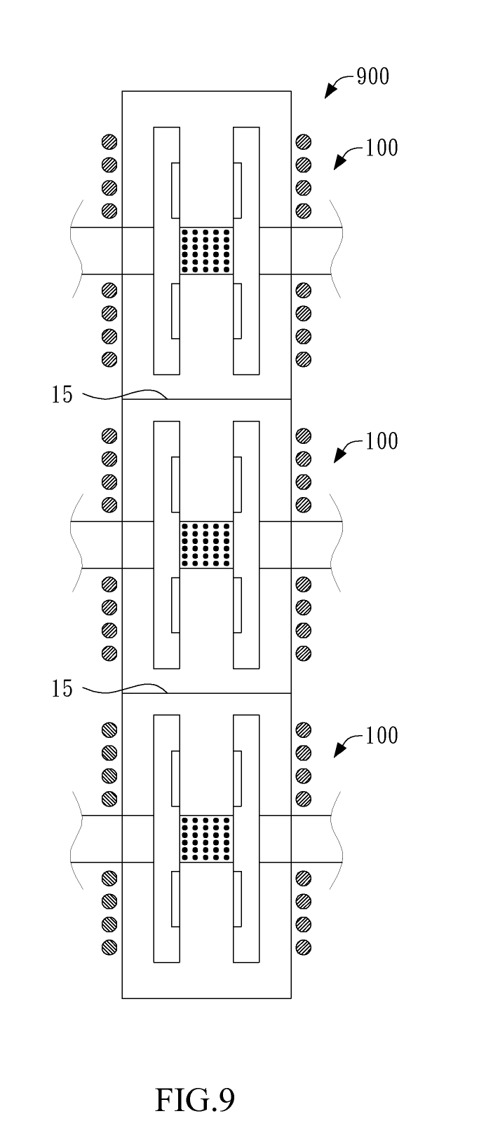

FIG. 9 shows a top view of an embodiment of a horizontally stacked CVD system. CVD system 900 may be made up of a number of CVD apparatuses 100 that are substantially horizontally or vertically linked or adjacent to each other. In certain embodiments, neighboring CVD apparatuses 100 are isolated from each other by chamber wall 15. Accordingly, each CVD apparatus 100 may be operated individually for performing its associated CVD process.

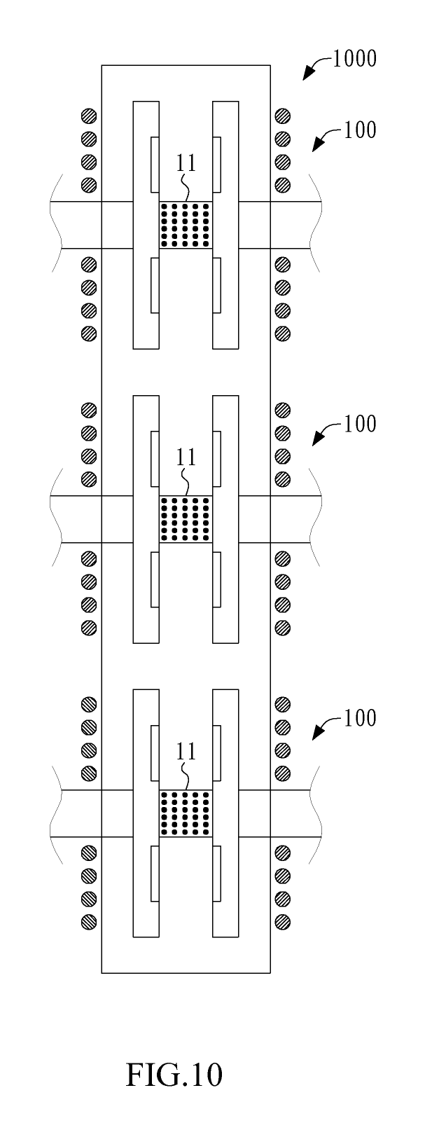

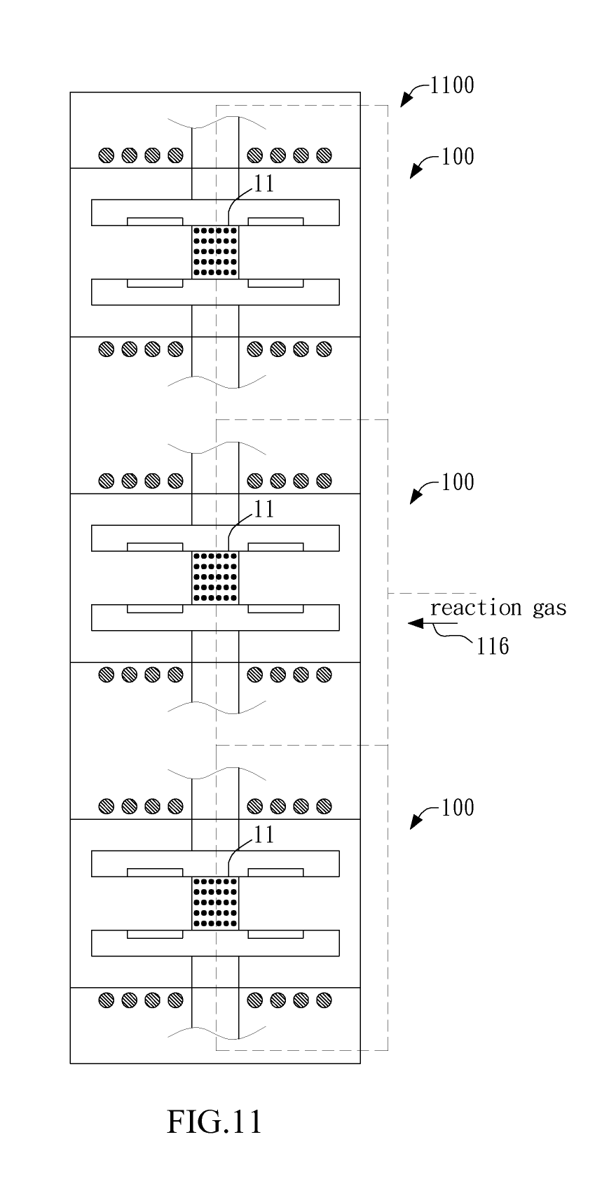

FIG. 10 shows a top view of an embodiment of horizontally stacked CVD system 1000 without the chamber wall. Accordingly, all CVD apparatuses 100 may be simultaneously operated, thereby facilitating mass production. In certain embodiments, each CVD apparatus 100 is individually provided with the reaction gas through individual showerheads 11. FIG. 11 shows a top view of an embodiment of another horizontally stacked CVD system 1100 without the chamber wall. In the embodiment, all CVD apparatuses are provided with the reaction gas through a common gas inlet 116 coupled to showerheads 11.

As described herein, susceptor 10 may be mounted in a substantially vertical or near vertical position. In certain embodiments described herein, susceptor 10 is in an approximately vertical position. However, in some embodiments, susceptor 10 may be inclined at an angle enough for the wafers supported and held on the holder 101 without locking the wafers to the holder 101 (e.g., as shown in the embodiment depicted in FIG. 1B).

It is to be understood the invention is not limited to particular systems described which may, of course, vary. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a device” includes a combination of two or more devices and reference to “a reactant gas” includes mixtures of reaction gases.

Further modifications and alternative embodiments of various aspects of the invention will be apparent to those skilled in the art in view of this description. Accordingly, this description is to be construed as illustrative only and is for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

What is claimed is:

1. A chemical vapor deposition (CVD) apparatus, comprising:
at least one susceptor mounted in a non-horizontal position;
at least one holder rotatably mounted on a first surface of the susceptor for holding one or more wafers, the holder being rotatable around a holder axis; and
a showerhead mounted at or near a center of the susceptor, wherein the showerhead is configured to release a reaction gas that flows radially toward a periphery of the susceptor during use.

2. The CVD apparatus of claim 1, wherein the holder has a mass center that is eccentric from the holder axis to allow the holder to have movement relative to the susceptor when the susceptor rotates.

3. The CVD apparatus of claim 1, wherein the holder includes a counterweight that makes a mass center of the holder eccentric from the holder axis.

4. The CVD apparatus of claim 3, wherein the counterweight comprises a mass coupled to an edge of the holder.

5. The CVD apparatus of claim 1, wherein the wafers are placed eccentric from the holder axis within a predetermined range.

6. The CVD apparatus of claim 1, further comprising a bearing placed around the holder to allow constrained relative rotation between the holder and the susceptor, and a mass attached at the bearing to result in an eccentric mass center.

7. The CVD apparatus of claim 6, wherein the bearing comprises an inner bearing fixed to the holder and attached with the mass, and an outer bearing fixed to the susceptor.

8. The CVD apparatus of claim 6, wherein the bearing comprises a top bearing fixed to the holder and attached with the mass, and a bottom bearing fixed to the susceptor.

9. The CVD apparatus of claim 1, wherein the showerhead is located between at least two susceptors that face each other.

10. The CVD apparatus of claim 1, further comprising at least one gas pipe line and at least one coolant pipe line located in the showerhead to provide the reaction gas and a coolant, respectively.

11. The CVD apparatus of claim 1, further comprising an exhaust outlet plate with a plurality of exhaust holes formed thereon, the exhaust outlet plate being located near a second surface of the susceptor opposite the first surface and being fixed with respect to a ground.

12. The CVD apparatus of claim 11, wherein the exhaust holes on an upper periphery of the exhaust outlet plate have a diameter larger than the exhaust holes on a lower periphery of the exhaust outlet plate.

13. The CVD apparatus of claim 1, further comprising a heater mounted away from a second surface of the susceptor opposite the first surface, wherein the heater provides heat for heating the wafers held on the holder during use.

14. The CVD apparatus of claim 1, wherein the susceptor comprises a rotating shell extended away from a second surface of the susceptor opposite the first surface, the rotating shell coupled to a gear that rotates the rotating shell and the susceptor during use.

15. The CVD apparatus of claim 1, further comprising a flange extending from the showerhead, the flange having nozzles formed on a surface of the flange facing the wafers.

16. The CVD apparatus of claim 1, further comprising a holder gear attached to a periphery of the holder, and a fixed gear attached to a fixed shell that extends from the showerhead, wherein, when the susceptor rotates, the holder rotates relative to the susceptor due to engagement between the holder gear and the fixed gear.

17. The CVD apparatus of claim 1, further comprising at least one susceptor roller configured to support and rotate the susceptor.

18. The CVD apparatus of claim 1, further comprising at least one holder roller configured to support and rotate the holder.

19. A chemical vapor deposition (CVD) apparatus, comprising:
at least one susceptor mounted in a non-horizontal position; and
at least one holder rotatably mounted on a first surface of the susceptor for holding one or more wafers, the holder being rotatable around a holder axis;
wherein the holder has a mass center that is eccentric from the holder axis to allow the holder to have movement relative to the susceptor when the susceptor rotates.

20. The CVD apparatus of claim 19, wherein the holder includes a counterweight that makes the mass center of the holder eccentric from the holder axis.

21. The CVD apparatus of claim 20, wherein the counterweight comprises a mass coupled to an edge of the holder.

22. The CVD apparatus of claim 19, wherein the wafers are placed eccentric from the holder axis within a predetermined range.

23. The CVD apparatus of claim 19, further comprising a bearing placed around the holder to allow constrained relative rotation between the holder and the susceptor, and a mass attached at the bearing to result in an eccentric mass center.

24. The CVD apparatus of claim 23, wherein the bearing comprises an inner bearing fixed to the holder and attached with the mass, and an outer bearing fixed to the susceptor.

25. The CVD apparatus of claim 23, wherein the bearing comprises a top bearing fixed to the holder and attached with the mass, and a bottom bearing fixed to the susceptor.

26. The CVD apparatus of claim 19, further comprising a showerhead mounted at or near a center of the susceptor, wherein the showerhead is located between at least two susceptors that face each other.

27. The CVD apparatus of claim 26, further comprising at least one gas pipe line and at least one coolant pipe line placed in the showerhead to provide a reaction gas and a coolant, respectively.

28. The CVD apparatus of claim 19, further comprising an exhaust outlet plate with a plurality of exhaust holes formed thereon, the exhaust outlet plate being located near a second surface of the susceptor opposite the first surface and being fixed with respect to a ground.

29. The CVD apparatus of claim 28, wherein the exhaust holes on an upper periphery of the exhaust outlet plate have a diameter larger than the exhaust holes on a lower periphery of the exhaust outlet plate.

30. The CVD apparatus of claim 19, further comprising a heater mounted away from a second surface of the susceptor opposite the first surface, wherein the heater provides heat for heating the wafers held on the holder.

31. The CVD apparatus of claim 19, wherein the susceptor comprises a rotating shell extended away from a second surface of the susceptor opposite the first surface, the rotating shell coupled to a gear that rotates the rotating shell and the susceptor during use.

32. The CVD apparatus of claim 19, further comprising a showerhead mounted at or near a center of the susceptor, and a flange extending from the showerhead, the flange having nozzles formed on a surface of the flange facing the wafers.

33. The CVD apparatus of claim 19, further comprising a showerhead mounted at or near a center of the susceptor, a holder gear attached to a periphery of the holder, and a fixed gear attached to a fixed shell that extends from the showerhead, wherein, when the susceptor rotates, the holder rotates relative to the susceptor due to engagement between the holder gear and the fixed gear.

34. The CVD apparatus of claim 19, further comprising at least one susceptor roller configured to support and rotate the susceptor.

35. The CVD apparatus of claim 19, further comprising at least one holder roller configured to support and rotate the holder.

36. A chemical vapor deposition (CVD) system, comprising:
a plurality of CVD apparatuses, wherein each CVD apparatuses is located substantially adjacent to at least one other CVD apparatus, and wherein at least one CVD apparatus comprises:
at least one susceptor mounted in a non-horizontal position; and
at least one holder rotatably mounted on a first surface of the susceptor for holding one or more wafers, the holder being rotatable around a holder axis;
wherein the holder has a mass center that is eccentric from the holder axis to allow the holder to have movement relative to the susceptor when the susceptor rotates.

37. The CVD system of claim 36, wherein the CVD apparatuses are substantially vertically stacked.

38. The CVD system of claim 36, wherein the CVD apparatuses are substantially horizontally stacked.

39. The CVD system of claim 36, further comprising at least one chamber wall located between at least two adjacent CVD apparatus.

40. The CVD system of claim 36, further comprising a showerhead located at a first location of the CVD system to provide a reaction gas, and an exhaust outlet located at a second location of the CVD system for removing an exhaust gas from the CVD system.
